(19) United States
(12) Patent Application Publication
(10) Pub. No.: US 2003/0217804 A1
(43) Pub. Date: Nov. 27, 2003

(54) Polymer micro-ring resonator device and fabrication method

(76) Inventors: Lingjie J. Guo, Ann Arbor, MI (US); Chung-Yen Chao, Ann Arbor, MI (US)

Correspondence Address: HARNESS, DICKEY & PIERCE, P.L.C., P.O. BOX 828, BLOOMFIELD HILLS, MI, 48303, US

(21) Appl. No.: 10/444,627

(22) Filed: May 23, 2003

Related U.S. Application Data
(60) Provisional application No. 60/383,010, filed on May 24, 2002.

(51) Int. Cl. B44C 1/165; H01L 21/44

(52) U.S. Cl. 156/230; 438/674

(57) ABSTRACT

A polymer micro-ring resonator and a method of manufacturing the same that is capable of providing reduced surface roughness and improved submicron gap separation between a waveguide and a micro-ring. Nanoimprinting is employed to achieve these advantages without the need for a final lithography and etching step. According to a first method, a hard mold is used to directly imprint a polymer film to form optical waveguides in micro-ring devices. A second method employs a template filling approach, which allows a thicker waveguide to be fabricated, as well as polymers that are difficult to directly imprint. Later buffering of the substrate is used to form pedestal structures under the waveguide and micro-ring for improved performance.

### CROSS-REFERENCE TO RELATED APPLICATIONS

This application claims the benefit of U.S. Ser. No. 60/383,010, filed May 24, 2002. The disclosure of the above application is incorporated herein by reference.

### GOVERNMENT RIGHTS

This invention was made with government support under Contract No. F49620-01-0-0135 awarded by the Air Force Office of Scientific Research. The Government has certain rights in the invention.

### FIELD OF THE INVENTION

The present invention relates to the fabrication of a polymer waveguide devices and, more particularly, relates to a polymer micro-ring or micro-disk resonator waveguide device.

### BACKGROUND AND SUMMARY OF THE INVENTION

Micro-ring resonator-based photonic devices have been researched extensively in recent years due to their important applications in integrated photonic circuits. These devices are typically in the form of a micro-ring closely coupled to a waveguide, which offers unique properties such as narrow bandwidth filtering, high quality factor, and compactness. A wide range of functionality has been exploited using micro-ring resonator-based devices for future optical communications, including channel add/drop filters, WDM demultiplexers, true ON-OFF switches, dispersion compensators, lasers, and enhanced nonlinear effects. To date, most of the micro-ring resonator devices have been fabricated in semiconductor materials by using a combination of electron-beam lithography and dry etching of semiconductor materials.

However, these prior art fabrication techniques may suffer for a number of disadvantages. For example, it is known that dry etching often leads to increased surface roughness, which results in large scattering loss. It is important to note that scattering loss is believed to be the main loss mechanism associated with fabricated micro-ring devices. Such a high loss places a significant limitation on the practical use of micro-resonator devices. That is, since scattering loss from surface roughness is proportional to(n_{WG}²-n_{C}²), where n_{WG} and n_{C} are the refractive indices of the waveguide and the cladding, respectively, the use of low refractive index polymers as used in the present invention will significantly reduce such loss. In addition, using the disclosed thermal reflow process could further reduce the surface roughness of the polymer waveguide, resulting in micro-ring resonators with extremely high quality-factor. Furthermore, polymer waveguides provide better coupling efficiency to optical fibers than prior art semiconductor waveguides due to the low index and the large cross section of the polymer waveguide. Still further, use of polymer materials also allows one to easily explore nonlinear optical effect for active devices by using many existing Nonlinear Optical (NLO) polymers. Devices such as tunable filters, optical switches, optical modulators can be made by using NLO or EO polymer materials.

Electron-beam lithography is known to be a slow serial patterning technique, which includes several limitations preventing efficient high volume manufacturing of micro-ring resonator based photonic integrated circuits.

Accordingly, there exists a need in the relevant art to provide a polymer micro-ring resonator that is capable of overcoming the disadvantages of the prior art.

Further areas of applicability of the present invention will become apparent from the detailed description provided hereinafter. It should be understood that the detailed description and specific examples, while indicating the preferred embodiment of the invention, are intended for purposes of illustration only and are not intended to limit the scope of the invention.

### BRIEF DESCRIPTION OF THE DRAWINGS

The present invention will become more fully understood from the detailed description and the accompanying drawings, wherein:

FIG. 1(a) is a schematic view illustrating a micro-ring resonator;

FIG. 1(b) is a graph illustrating narrow bandwidth filter behavior;

FIG. 2(a) is a flowchart illustrating the process steps of a first embodiment of the present invention;

FIG. 2(b) is a flowchart illustrating the process steps of a second embodiment of the present invention;

FIG. 3(a) is a SEM photograph illustrating a waveguide and micro-ring trench formed in a mold;

FIG. 3(b) is a SEM photograph illustrating a waveguide and micro-ring;

FIG. 4(a) is a SEM photograph illustrating a waveguide disposed atop of a pedestal structure;

FIG. 4(b) is a SEM photograph illustrating a waveguide and micro-ring disposed atop of a pedestal structure;

FIG. 5(a) is a SEM photograph of a waveguide and micro-ring in a racetrack configuration;

FIG. 5(b) is a SEM photograph of a waveguide and micro-ring in a microdisk configuration

FIG. 6(a) is a SEM photograph of a waveguide and micro-ring before annealing;

FIG. 6(b) is a SEM photograph of a waveguide and micro-ring annealed at 85° C. for 120 seconds;

FIG. 6(c) is a SEM photograph of a waveguide and micro-ring annealed at 95° C. for 60 seconds;

FIG. 7(a) is a graph illustrating the transmission spectrum through the micro-ring resonator device of the present invention; and

FIG. 7(b) is a graph illustrating the transmission spectrum through a micro-ring resonator device having a pair of waveguides on opposing sides of the micro-ring of the present invention.

### DETAILED DESCRIPTION OF THE PREFERRED EMBODIMENTS

The following description of the preferred embodiments is merely exemplary in nature and is in no way intended to limit the invention, its application, or uses.

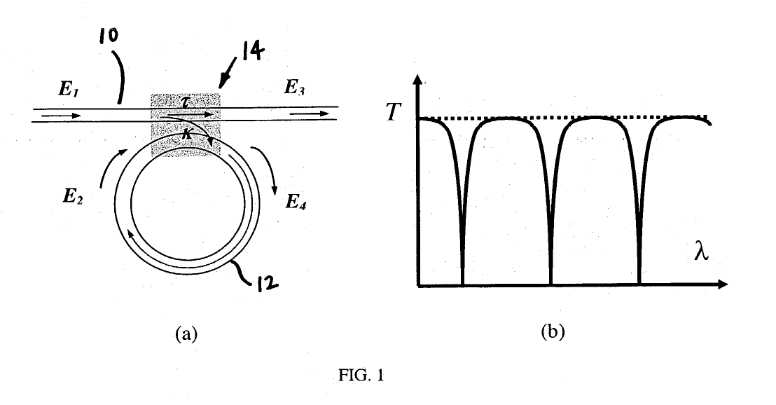

By way of background, it is believed that a brief discussion of the principles of micro-ring resonators is useful. With particular reference to FIG. 1(a), a waveguide 10 is illustrated coupled with a micro-ring 12. An input (E₁), an output (E₃), and circulating field inside micro-ring 12 (E₂ and E₄) can be described by the following coupled-mode equations

E₃=αᵢ(τE₁+jκE₂ )

E₄=αᵢ(jκE₁+τE₂) (1)

where υ and κ is the amplitude transmission and coupling coefficient, respectively, and αᵢ is the insertion loss due to waveguide 10 mode mismatch in coupling region 14. By introducing a single-pass amplitude attenuation factor a, it is appropriate to state E₂=ae^{jφ}E₄, where φ is the single-pass phase experienced by light traveling inside micro-ring 12, which is equal to 2πn_{eff}L/λ. Here, n_{eff} is the effective refractive index of the propagation mode, L is the circumference of micro-ring 12, and λ is the vacuum wavelength. Together with Eq. (1), the transmission through waveguide 10, when coupled to micro-ring 12, is as follows:

$$T = \frac{{I}_{3}}{{I}_{1}} = {\vert \frac{( {α}_{i} τ ) - {α}_{i}^{2} a {ⅇ}^{j φ}}{1 - a ( {α}_{i} τ ) {ⅇ}^{j φ}} \vert}^{2} \qquad ( 2 )$$

Accordingly, as set forth in Eq. (2), resonance occurs as φ=2mπ (m is an integer), and the transmission through waveguide 10 shows a periodic dip behavior as a function of input wavelength (schematically illustrated in FIG. 1(b)). It is this narrow bandwidth filter behavior that makes micro-ring devices very attractive for integrated WDM add/drop filter applications.

In micro-ring resonators, the coupling coefficient plays an important role in determining the device characteristics. Generally, the coupling coefficient depends exponentially on the gap distance between the micro-ring and the straight waveguide. In order to have sufficient coupling between the micro-ring and the straight waveguide, the gap between the micro-ring and waveguide should preferably be small; alternatively, “racetrack” geometry can be used where the overall length of the coupling region is increased to enhance the coupling. According to the present invention, it has been determined that for a typical polymer with refractive index of 1.55, the polymer channel separating waveguide 10 and micro-ring 12 should be at least 1.5 μm high in order to support single mode propagation with low loss and good confinement with a gap width at the coupling region of about 100 to 200 nm. However, to fabricate polymer waveguide and micro-ring devices, especially closely coupled waveguides and micro-rings with gap distance of 100 to 200 nm and height of at least 1.5 μm, conventional patterning and RIE processes are very difficult.

According to the teachings of the present invention, a direct imprinting techniques and a template filling technique are used to fabricate micro-ring resonators. A variety of optical quality polymers may be used to form the micro-ring waveguide structures uses these techniques.

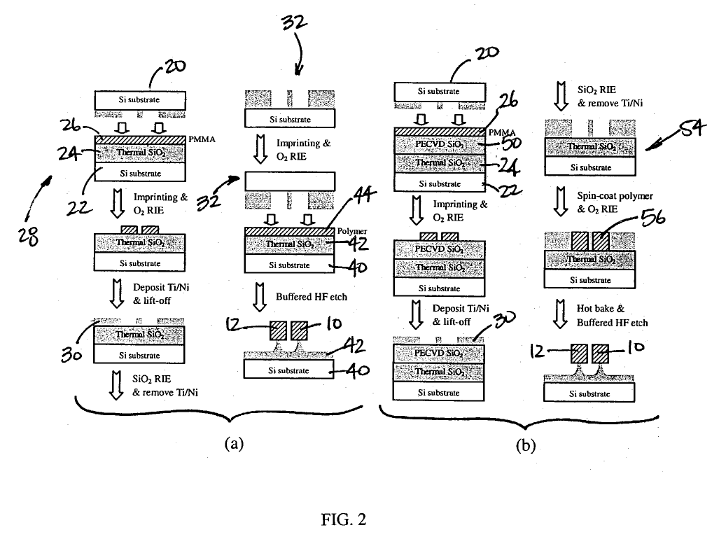

A first preferred embodiment includes direct imprinting to create polymer waveguides and micro-rings, which is schematically illustrated in FIG. 2(a), and begins with first preparing a separate imprinting mold. This mold 20 includes a silicon substrate having a 200 to 400 nm thick layer of thermally grown silicon dioxide thereon. A subsequent layer of spin-coated 4% 950 k polymethylmethacrylate (PMMA) is applied thereto. The PMMA layer is preferably about 200 to 250 nm thick. This assembly is then baked at about 180° C. for about 30 minutes. Following baking, the assembly is patterned using electron beam lithography to create features in the PMMA layer. These features are transferred into silicon dioxide underneath by CHF₃/CF₄ reactive ion etch (RIE) and the remaining PMMA is removed via acetone. The assembly is then coated with surfactant to form a shallow mold 20 used in the succeeding nanoimprinting step.

After fabricating shallow mold 20, it may be used to create a subsequent mold having deep features through a nanoimprint technique according to the present invention. A silicon substrate 22 is first grown with a 2 μm thick silicon dioxide layer 24, which is later spin-coated with 4% 15 k PMMA to form a PMMA layer 26, which together define an assembly 28. Assembly 28 is closely contacted with shallow mold 20. Assembly 28 and shallow mold 20 are brought together under high pressure of about 900 psi and high temperature of about 150° C. for about 10 minutes in order to transfer the pattern of shallow mold 20 to PMMA layer 26. Following cooling, assembly 28 is separated from mold 20 and the residual PMMA layer is removed via O₂ RIE.

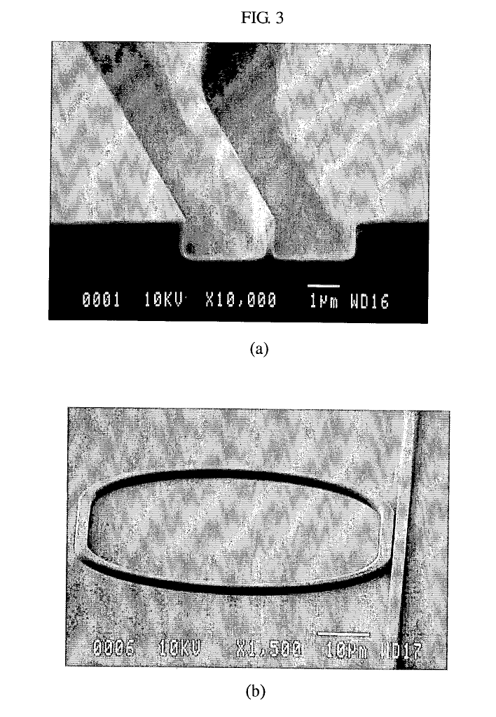

To create features in assembly 28, hard mask 30 is used, preferably a metal material such as Ti/Ni. Metal mask 30 is evaporated on silicon dioxide layer 24 and then lifted off using PRS 2000 (photo resist stripper) solution. Consequently, the pattern in metal mask 30 is transferred into silicon dioxide layer 24 via CHF₃/CF₄ RIE. The remaining metal mask 30 is then removed via NH₄OH:H₂O₂:.H₂O (1:1:5) solution. This arrangement is then coated with surfactant as a deep mold 32 to create 2 μm high polymer waveguides in the following step. As best seen in FIG. 3(a), a scanning electron microscopy (SEM) picture of a fabricated deep mold 32 is provided having a micro-racetrack shape.

Referring again to FIG. 2(a), deep mold 32 is then used to imprint directly a polymer spin coating on a thermally grown oxide layer to create the desired waveguide and micro-ring structure. To this end, a silicon member 40 is grown with a 2 μm thick silicon dioxide layer 42 and spin-coated with a polymer layer 44 of polymethylmethacrylate (PMMA), polystyrene (PS), or polycarbonate (PC), which forms the core of waveguide 10 and micro-ring 12. Preferably, the polymer spin coating is a PMMA polymer because of its high optical quality. In order to minimize the thickness of any residual polymer layer after imprinting so as to facilitate further device processing, it is preferable that the initial PMMA thickness is about 200 nm, which is thinner than the final desired waveguide and micro-ring thickness of 1.5 μm. This implies that a large amount of polymer needs to be displaced in order to fill in the mold trough region during imprinting. The residual polymer layer is removed by O₂ RIE. To provide better light confinement, the sample is immersed in buffered HF to isotropically etch part of silicon dioxide layer 24 beneath waveguide 10 and micro-ring 12 for creating the pedestal structures seen in the figures.

Consequently, it has been found that the conditions for imprinting need to be modified accordingly to ensure that the patterns are properly transferred from deep mold 32 to polymer layer 44. For example, it was determined that high pressure (i.e. about 75 kg/cm²) serves to assist the polymer flow. Additionally, an imprinting temperature of about 175° C. was selected. Polymer temperatures greater than about 190° C. have been found to reduce adversely the viscosity of the polymer, which may lead to non-uniform pattern thickness after imprinting due to the non-flatness of the wafer surface. In the present embodiment, it was found that by extending the imprinting time to about 10 minutes, the polymer has sufficient time to move so as to achieve a uniform pattern thickness. With these optimized imprinting conditions, it is possible to now successfully imprint polymer micro-ring resonator structures. A fabricated micro-ring device according to the principles of the present invention is illustrated in FIG. 3(b), which consists of PMMA waveguides and micro-rings of 1.5 μm in height with a coupling gap distance of 200 nm between micro-ring 12 and waveguide 10.

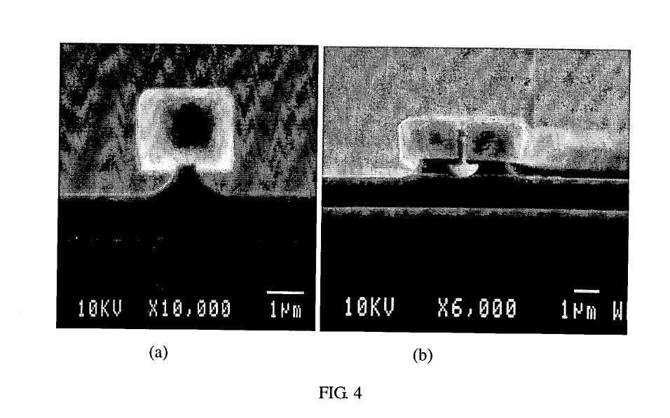

In order to improve field (light) confinement in waveguide 10 and micro-ring 12, it is preferable to optionally employ buffered HF to isotropically etch the SiO₂ beneath waveguide 10 and micro-ring 12 to create pedestal structures there below (see FIGS. 2(a) and 4(a)-(b)).

During separation of the mold from the imprinted polymer waveguide and micro-ring, it is important to avoid breakage of the curved sections of waveguide 10. This breakage may be avoided by ensuring the surface of the mold and the substrate remain parallel to each other during separation.

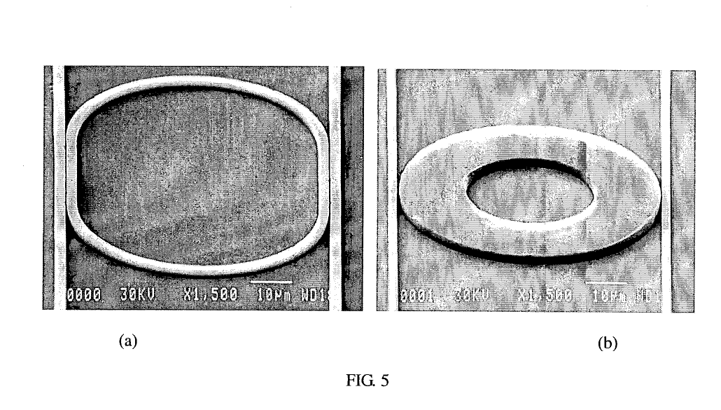

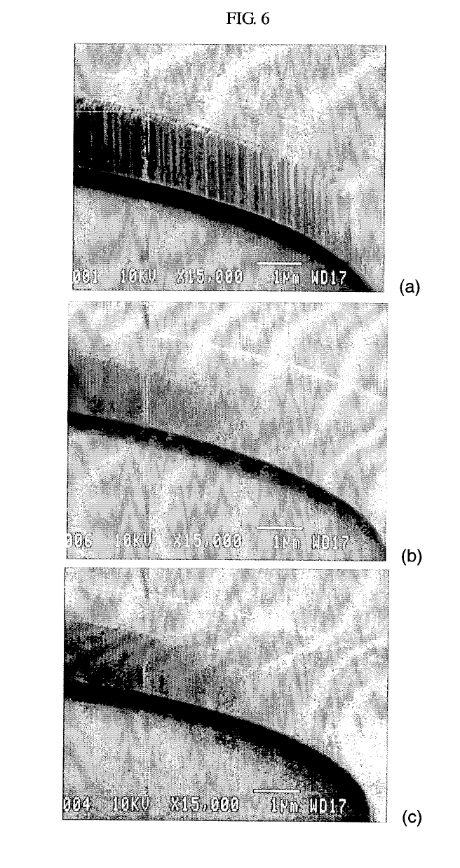

Polymers that are suitable for forming micro-ring and micro-disk resonators are not limited to PMMA. That is, similar processing conditions can be used to fabricate polystyrene (PS) microresonator devices. Alternatively, polymers that possess tough mechanical property may be used, such as polycarbonate (PC). As best seen in FIG. 5, imprinted PC micro-racetrack (FIG. 5(a)) and micro-disk (FIG. 5(b)) structures with a waveguide and micro-ring height of 2 μm are illustrated. By way of non-limiting example, the polycarbonate used in the present embodiment included a molecular weight of 18,000 and a glass transition temperature of 150° C. Accordingly, it was necessary to raise the imprinting temperature to about 220° C. During fabrication, polycarbonate micro-ring and micro-disk remained intact during mold separation. The increased refractive index of 1.6 of polycarbonate relative to PMMA provides improved optical field confinement, while the higher glass transition temperature of polycarbonate is more thermally stable than that of PMMA. However, it should be noted that the toughness of polycarbonate might make it difficult to cleave the polycarbonate waveguide for input and output coupling.

A second preferred embodiment is illustrated in FIG. 2(b) and includes a template filling method that facilitates the fabrication of thicker polymer waveguides and micro-rings, as well as for polymers that are not easily imprinted directly. This second preferred embodiment begins with first preparing a separate imprinting mold. This mold 20 includes a silicon substrate having a 200 to 400 nm thick layer of thermally grown silicon dioxide thereon. A subsequent layer of spin-coated 4% 950 k polymethylmethacrylate (PMMA) is applied thereto. The PMMA layer is preferably about 200 to 250 nm thick. This assembly is then baked at about 180° C. for about 30 minutes. Following baking, the assembly is patterned using electron beam lithography to create features in the PMMA layer. These features are transferred into silicon dioxide underneath by CHF₃/CF₄ reactive ion etch (RIE) and the remaining PMMA is removed via acetone. The assembly is then coated with surfactant to form a shallow mold 20 used in the succeeding nanoimprinting step.

After fabricating shallow mold 20, it may be used to create a deep features through a nanoimprint technique according to the present invention. A silicon substrate 22 is produced having a 2 μm thick thermally grown silicon dioxide layer 24 and a 2 μm thick Plasma Enhanced Chemical Vapor Deposition (PECVD) silicon dioxide layer 50. A subsequent layer of spin-coated 4% 15 k polymethylmethacrylate (PMMA) is applied thereto to form a PMMA layer 26. Silicon substrate 22, silicon dioxide layer 24, PECVD layer 50, and PMMA layer 26 together define an assembly 52. Assembly 52 is then patterned using the nanoimprint technique using shallow mold 20. Specifically, assembly 52 and shallow mold 20 are brought together under high pressure of about 900 psi and high temperature of about 150° C. for about 10 minutes in order to transfer the pattern of shallow mold 20 to PMMA layer 26. Following cooling, assembly 52 is separated from mold 20 and the residual PMMA layer is removed via O₂ RIE.

To create features in assembly 52, hard mask 30 is used, preferably a metal material such as Ti/Ni. Metal mask 30 is evaporated on PECVD layer 50 and then lifted off using PRS 2000 (photo resist stripper) solution. Those portions of PECVD layer 50 that are not protected by hard mask 30 is anisotropically etched via CHF₃/CF4 RIE. The remaining metal mask 30 is then removed via NH₄OH:H₂O₂:.H₂O (1:1:5) solution. The resultant member 54 is spin-coated with a polymer layer 56 that can fill in trenches to form waveguide 10 and micro-ring 12. Preferably, polymer layer 56 should be planarized by a flat silicon mold using the nanoimprint technique. After planarization, some bubbles appeared in the trenches. These bubbles can be removed by heating the sample to about 130° C. for several minutes. The residual polymer layer is removed by O₂ RIE. To provide better light confinement, the sample is immersed in buffered HF to isotropically etch part of silicon dioxide layer 24 beneath waveguide 10 and micro-ring 12 for creating the pedestal structures seen in the figures.

The final polymer micro-ring resonator structure formed by the second preferred embodiment is very similar to that obtained by the first preferred embodiment. However, an advantageous unique to the present embodiment is the ability to avoid the possible defect formation during mold separation. As a result, taller structures may be fabricated. Additionally, the present embodiment is readily adaptable for use with many polymer materials that are otherwise difficult to directly imprint.

According to the principles of the present invention, polymer micro-ring resonators are successfully fabricated using a nanoimprint technique. A first method employs the use of direct imprinting to fabricate PMMA and PS micro-ring devices of less than 1.5 μm in height. This first method may also be used to fabricate taller micro-ring structures through the use of mechanically stronger polymers, such as polycarbonate. Alternatively, a second method of fabrication is provided that employs a template filling method to fabricate larger micro-ring devices than could otherwise be fabricated using the aforementioned direct imprinting technique. This second method of fabrication may also be used in connection with those polymers that are traditionally difficult to directly imprint.

Additionally, according to the principles of the present invention, a thermal-flow process to reduce surface roughness of polymer waveguides is provided. This process further provides an effective way to modify the submicron gap separation that controls the coupling of the optical field to the micro-ring waveguide. The polymer micro-ring devices, made from polystyrene (PS), were fabricated by using a nanoimprinting technique. After the polymer waveguide had been formed, the samples are heated to a temperature close to the glass transition temperature of PS for a predetermined amount of time. This heat treatment reduces the viscosity of PS and enhances its fluidity. SEM characterization clearly shows that the sidewall roughness can be greatly reduced, which is a result of surface tension effect of the polymer. Higher temperature tends to produce smoother surface (see FIG. 5).

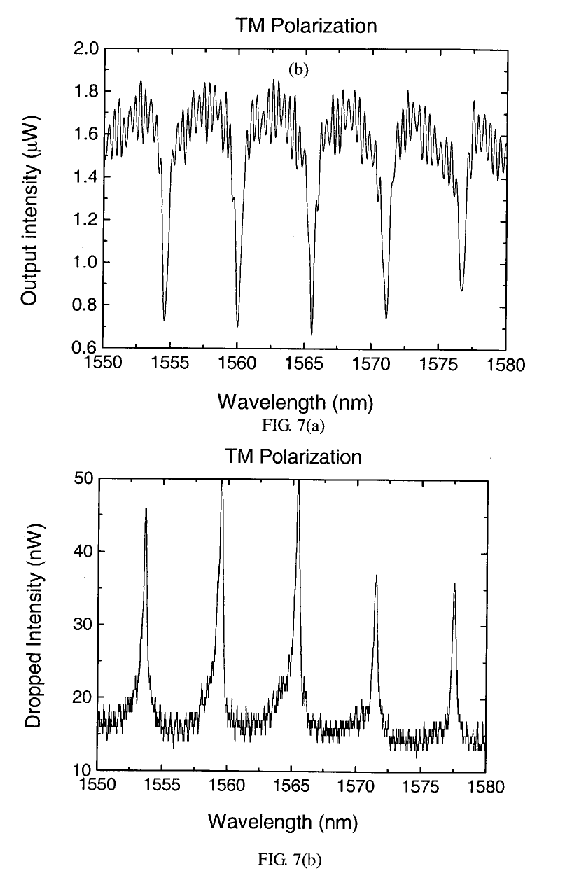

Lastly, as best seen in FIGS. 7(a)-(b), optical results of the transmission spectrum through the micro-ring resonator device of the present invention are illustrated. FIG. 7(a) illustrates the filter behaviour obtained from the output port E₃ of the microresonator of the present invention. FIG. 7(b) illustrates the filter behaviour obtained from the drop port from a second waveguide, separate from waveguide 10, disposed adjacent to micro-ring 12. In this example, second waveguide (not shown) is spaced on an opposing side of micro-ring 12 from waveguide 10.

The description of the invention is merely exemplary in nature and, thus, variations that do not depart from the gist of the invention are intended to be within the scope of the invention. Such variations are not to be regarded as a departure from the spirit and scope of the invention.

What is claimed is:

1. A method of forming a microresonator, said method comprising:
providing a mold;
forming an inversed pattern of a predetermined shape in said mold;
providing a substrate having a polymer layer;
imprinting said inversed pattern of said mold into said polymer layer of said substrate under pressure;
at least partially curing said polymer layer prior to removal of said mold from said substrate; and
selectively removing undesired sections of said substrate.

2. The method according to claim 1, further comprising:
heating said polymer layer to at least its glass transition temperature.

3. The method according to claim 1 wherein said predetermined shape includes a micro-ring and a waveguide structure.

4. The method according to claim 1 wherein said selectively removing undesired sections of said substrate includes exposing said substrate to a buffered HF bath to produce a pedestal structure between said substrate and at least one of a waveguide and a micro-ring.

5. The method according to claim 1 wherein said forming an inversed pattern of a predetermined shape in said mold includes:
providing a first silicon substrate having an about 200 to 400 nm thick layer of thermally grown silicon dioxide;
spin-coating a polymethylmethacrylate (PMMA) layer on said first silicon substrate;
baking said first silicon substrate and PMMA layer;
patterning said PMMA layer using electron beam lithography to define a plurality of predetermined features in said PMMA layer;
transferring said predetermined features into said silicon dioxide via reactive ion etching;
removing said PMMA layer to form a first mold impression;
coating said first mold impression with surfactant;
providing a second silicon substrate having an about 2 μm thick layer of thermally grown silicon dioxide;
spin-coating a polymethylmethacrylate (PMMA) layer on said second silicon substrate;
engaging said first mold impression against said polymethylmethacrylate (PMMA) layer of said second silicon substrate under pressure whereby transferring the pattern of said first mold impression to said polymethylmethacrylate layer of said second silicon substrate;
applying a metal mask to said silicon dioxide layer of said second silicon substrate;
removing said polymethylmethacrylate (PMMA) layer of said second silicon substrate;
etching said predetermined pattern into said silicon dioxide layer of said second substrate to form a second mold impression; and
coating said second mold impression with surfactant to form said inversed pattern of said predetermined shape.

6. The method according to claim 1 wherein said imprinting said inversed pattern of said mold into said polymer layer of said substrate under pressure includes displacing at least a portion of said polymer into said inversed pattern in said mold.

7. A method of forming a microresonator, said method comprising:
providing a mold;
forming an inversed pattern of a predetermined shape in said mold;
providing a substrate;
depositing a thermally grown silicon dioxide layer on said substrate;
depositing a PECVD silicon dioxide layer upon said thermally grown silicon dioxide layer via Plasma Enhanced Chemical Vapor Deposition (PECVD);
depositing a polymethylmethacrylate (PMMA) layer upon said PECVD silicon dioxide layer;
imprinting said inversed pattern of said mold into said polymethylmethacrylate (PMMA) layer under pressure;
applying a metal mask to said PECVD silicon dioxide layer;
removing said polymethylmethacrylate (PMMA) layer;
etching said predetermined pattern into said PECVD silicon dioxide layer to form at least one channel; and
applying a polymer within said at least one channel;
removing said PECVD silicon dioxide layer; and
selectively removing undesired sections of said thermally grown silicon dioxide layer.

8. The method according to claim 7, further comprising:
heating said polymer layer to at least its glass transition temperature.

9. The method according to claim 7 wherein said selectively removing undesired sections of said thermally-grown silicon dioxide layer includes exposing said substrate to a buffered HF bath to produce a pedestal structure between said substrate and said polymer.

10. The method according to claim 7 wherein said forming an inversed pattern of a predetermined shape in said mold includes:
providing a mold silicon substrate having an about 200 to 400 nm thick layer of thermally grown silicon dioxide;
spin-coating a polymethylmethacrylate (PMMA) layer on said mold silicon substrate;
baking said mold silicon substrate and PMMA layer;
patterning said PMMA layer using electron beam lithography to define a plurality of predetermined features in said PMMA layer;
transferring said predetermined features into said silicon dioxide via reactive ion etching;
removing said PMMA layer to form a mold impression; and
coating said mold impression with surfactant.

11. A polymer microresonator device having a waveguide and a micro-ring, said micro-ring being adjacent said waveguide, a process of manufacturing said microresonator device comprising:
providing a mold;
forming an inversed pattern of a predetermined shape in said mold;
providing a substrate having a polymer layer;
imprinting said inversed pattern of said mold into said polymer layer of said substrate under pressure;
at least partially curing said polymer layer prior to removal of said mold from said substrate; and
selectively removing undesired sections of said substrate to form said waveguide and said micro-ring upon a pedestal structure.

12. The polymer microresonator device according to claim 11 wherein said process further comprises:
heating said polymer layer to at least its glass transition temperature.

13. The polymer microresonator device according to claim 11 wherein said process step of selectively removing undesired sections of said substrate to form said waveguide comprises:
exposing said substrate to a buffered HF bath.

14. The polymer microresonator device according to claim 11 wherein said process step of forming an inversed pattern of a predetermined shape in said mold comprises:
providing a first silicon substrate having an about 200 to 400 nm thick layer of thermally-grown silicon dioxide;
spin-coating a polymethylmethacrylate (PMMA) layer on said first silicon substrate;
baking said first silicon substrate and PMMA layer;
patterning said PMMA layer using electron beam lithography to define a plurality of predetermined features in said PMMA layer;
transferring said predetermined features into said silicon dioxide via reactive ion etching;
removing said PMMA layer to form a first mold impression;
coating said first mold impression with surfactant;
providing a second silicon substrate having an about 2 μm thick layer of thermally grown silicon dioxide;
spin-coating a polymethylmethacrylate (PMMA) layer on said second silicon substrate;
engaging said first mold impression against said polymethylmethacrylate (PMMA) layer of said second silicon substrate under pressure whereby transferring the pattern of said first mold impression to said polymethylmethacrylate layer of said second silicon substrate;
applying a metal mask to said silicon dioxide layer of said second silicon substrate;
removing said polymethylmethacrylate (PMMA) layer of said second silicon substrate;
etching said predetermined pattern into said silicon dioxide layer of said second substrate to form a second mold impression; and
coating said second mold impression with surfactant to form said inversed pattern of said predetermined shape.

15. The polymer microresonator device according to claim 11 wherein said process step of imprinting said inversed pattern of said mold into said polymer layer of said substrate under pressure comprises displacing at least a portion of said polymer into said inversed pattern in said mold.

16. A microresonator device having a waveguide and a micro-ring, said micro-ring being adjacent said waveguide, a process of manufacturing said microresonator device comprising:
providing a mold;
forming an inversed pattern of a predetermined shape in said mold;
providing a substrate;
depositing a thermally grown silicon dioxide layer on said substrate;
depositing a PECVD silicon dioxide layer upon said thermally grown silicon dioxide layer via Plasma Enhanced Chemical Vapor Deposition (PECVD);
depositing a polymethylmethacrylate (PMMA) layer upon said PECVD silicon dioxide layer;
imprinting said inversed pattern of said mold into said polymethylmethacrylate (PMMA) layer under pressure;
applying a metal mask to said PECVD silicon dioxide layer;
removing said polymethylmethacrylate (PMMA) layer;
etching said predetermined pattern into said PECVD silicon dioxide layer to form at least one channel; and
applying a polymer within said at least one channel;
removing said PECVD silicon dioxide layer; and
selectively removing undesired sections of said thermally grown silicon dioxide layer to form said waveguide and said micro-ring upon a pedestal structure.

17. The microresonator device according to claim 16 wherein said process further comprises:
heating said polymer layer to at least its glass transition temperature.

18. The microresonator device according to claim 16 wherein said process step of selectively removing undesired sections of said thermally grown silicon dioxide layer to form said waveguide and said micro-ring upon a pedestal structure includes exposing said substrate to a buffered HF bath.

19. The microresonator device according to claim 16 wherein said process step of forming an inversed pattern of a predetermined shape in said mold includes:
providing a mold silicon substrate having an about 200 to 400 nm thick layer of thermally grown silicon dioxide;
spin-coating a polymethylmethacrylate (PMMA) layer on said mold silicon substrate;
baking said mold silicon substrate and PMMA layer;
patterning said PMMA layer using electron beam lithography to define a plurality of predetermined features in said PMMA layer;
transferring said predetermined features into said silicon dioxide via reactive ion etching;
removing said PMMA layer to form a mold impression; and
coating said mold impression with surfactant.
